(19) United States
(12) Patent Application Publication
(10) Pub. No.: US 2015/0041314 A1
(43) Pub. Date: Feb. 12, 2015

(54) ANNULAR MEMBER AND FILM-FORMING DEVICE IN WHICH SAME IS USED

(71) Applicant: KYOCERA Corporation, Kyoto-shi, Kyoto (JP)

(72) Inventor: Tomoyuki Inoue, Higashiomi-shi (JP)

(21) Appl. No.: 14/388,196

(22) PCT Filed: Mar. 8, 2013
(86) PCT No.: PCT/JP2013/056448

§ 371 Date: Sep. 25, 2014

(30) Foreign Application Priority Data
Mar. 29, 2012 (JP) 2012-077970
Jul. 30, 2012 (JP) 2012-168046

(51) Int. Cl. H01L 21/687; C23C 14/50

(52) U.S. Cl. CPC H01L 21/68735; C23C 14/50
USPC 204/298.15

(57) ABSTRACT

An annular member 10 according to an aspect of the invention surrounds the periphery of a substrate to be processed 2. The annular member 10 includes an annular main body 11 which is made of a ceramic sintered body or quartz glass, and has at least one main surface S1. The main body 11 has a groove portion G disposed on the main surface S1 and a plurality of projections 14 protruded from a bottom surface B of the groove portion G. A film forming apparatus 1 according to an aspect of the invention includes the annular member 10 and a reaction chamber 4 in which the annular member 10 is disposed, and which performs formation of a metal film 3 on the substrate to be processed 2. The groove portion G of the annular member 10 is exposed to the inside of the reaction chamber 4.

### TECHNICAL FIELD

The present invention relates to an annular member which is used in a film forming apparatus that forms a film in a process of manufacturing a semiconductor element or in a process of manufacturing a flat panel display (FPD), and to a film forming apparatus using the annular member.

### BACKGROUND ART

In the related art, in a process of manufacturing a semiconductor element or in a process of manufacturing an FPD, a film forming apparatus is used to form a metal film on a substrate to be processed, such as a semiconductor wafer or a glass substrate. In the film forming apparatus, when the metal film is formed on the substrate to be processed in a reaction chamber, an annular member which surrounds the periphery of the substrate to be processed is used so as to suppress adhesion of the metal film to other members.

For example, in the specification of U.S. Patent Application Publication No. 2006/0219172, there is disclosed an annular member (deposition ring 100) which includes an annular main body (ring body 110) provided with a main surface (first surface 111) and a groove portion (groove 120) formed on the main surface.

In paragraph [0022] of the specification of U.S. Patent Application Publication No. 2006/0219172, it is disclosed that ceramics are used as a material of the annular member. When ceramics are used as the material of the annular member, since ceramics generally have a lower thermal expansion coefficient than metal, the thermal expansion coefficient of the annular member is likely to be lower than the thermal expansion coefficient of the metal film that is formed on the substrate to be processed.

When a metal film is formed on a substrate to be processed in the above-described film forming apparatus, the metal film is deposited in the groove portion of the annular member inside the heated reaction chamber. Therefore, when the temperature inside the reaction chamber decreases after forming the metal film on the substrate to be processed, the metal film inside the groove portion contracts more than the annular member because of the difference between the thermal expansion coefficient of the annular member and the thermal expansion coefficient of the metal film. Accordingly, thermal stress is applied to the annular member, and a crack may occur in the annular member. As a result, reliability of the annular member may easily deteriorate.

### SUMMARY OF INVENTION

The present invention provides an annular member which meets a demand for increasing reliability and a film forming apparatus using the same.

An annular member according to an aspect of the present invention surrounds the periphery of a substrate to be processed. The annular member includes an annular main body which is made of a ceramic sintered body or quartz glass and has at least one main surface. The main body has a groove portion disposed on the main surface and a plurality of projections protruded from a bottom surface of the groove portion.

A film forming apparatus according to an aspect of the present invention includes the above-described annular member and a reaction chamber in which the annular member is disposed and a metal film is formed on the substrate to be processed. The groove portion of the annular member is exposed to the inside of the reaction chamber.

According to the annular member of an aspect of the present invention, the main body has the plurality of projections protruded from the bottom surface of the groove portion. Accordingly, when the temperature of the annular member decreases after forming the metal film on the substrate to be processed, thermal stress to be applied to the annular member can be dispersed and the annular member which has good reliability can be obtained.

According to the film forming apparatus of an aspect of the present invention, the film forming apparatus includes the above-described annular member, so that the film forming apparatus which has good reliability can be obtained.

### BRIEF DESCRIPTION OF DRAWINGS

FIG. 1 is a cross-sectional view illustrating a film forming apparatus using an annular member of a first embodiment of the invention.

FIG. 2 is a top view of the annular member illustrated in FIG. 1.

FIG. 3 is an enlarged view of Part R1 in FIG. 2.

FIG. 4 is a cross-sectional view illustrating a part of the annular member illustrated in FIG. 2 cut in a thickness direction (Z direction).

FIG. 5(a) is a partially enlarged view of FIG. 4, and FIG. 5(b) is a view illustrating a metal film deposited inside a groove portion in FIG. 5(a).

FIG. 6(a) is a perspective view of a projection in the annular member of the first embodiment of the invention, FIG. 6(b) is a perspective view of a projection in an annular member of a second embodiment of the invention, and FIG. 6(c) is a perspective view of a projection in an annular member of a third embodiment of the invention.

FIG. 7(a) is a cross-sectional view in which the projection in FIG. 6(a) is cut in a thickness direction, FIG. 7(b) is a cross-sectional view in which the projection in FIG. 6(b) is cut in a thickness direction, and FIG. 7(c) is a cross-sectional view in which the projection in FIG. 6(c) is cut in a thickness direction.

FIG. 8 is a side view of a cutting tool which is used when the annular member of the first embodiment of the invention is manufactured.

FIG. 9 is a cross-sectional view in which a part of an annular member of a fourth embodiment of the invention is cut in a thickness direction.

FIG. 10(a) is a partially enlarged view of a top view of an annular member of a fifth embodiment of the invention, and FIG. 10(b) is a cross-sectional view in which the annular member in FIG. 10(a) is cut along line A-A in a thickness direction.

FIG. 11(a) is a perspective view of a projection of an annular member of a sixth embodiment of the invention, and FIG. 11(b) is a partially enlarged view of a surface of the projection illustrated in FIG. 11(a).

FIG. 12(a) is a cross-sectional view in which a part of an annular member of a seventh embodiment of the invention is cut in a thickness direction, FIG. 12(b) is a perspective view of the projection of the annular member in

FIG. 12(a), and FIG. 12(c) is a cross-sectional view in which the projection in FIG. 12(b) is cut in a thickness direction.

### DESCRIPTION OF EMBODIMENTS

### First Embodiment

### Film Forming Apparatus

Hereinafter, a film forming apparatus using an annular member according to a first embodiment of the invention will be described in detail with reference to the drawings.

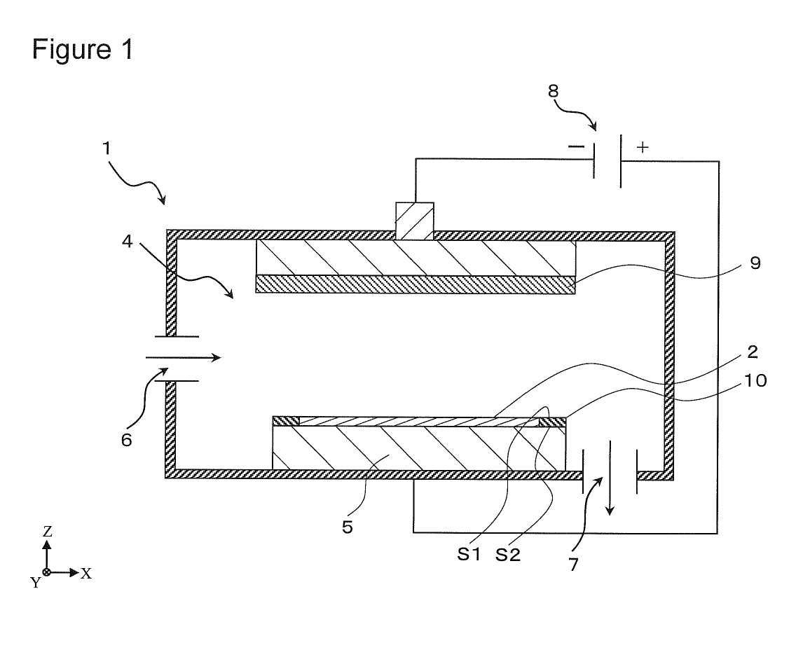

As illustrated in FIG. 1, a film forming apparatus 1 of the invention is a sputtering apparatus which forms a metal film 3 by sputtering on a substrate to be processed 2, such as a semiconductor wafer or a glass substrate, in a process of manufacturing a semiconductor element or in a process of manufacturing an FPD.

The film forming apparatus 1 includes: a reaction chamber 4 which accommodates the substrate to be processed 2 inside and performs formation of the metal film 3 on the substrate to be processed 2; a mounting member 5, such as an electrostatic chuck on which the substrate to be processed 2 is mounted, inside the reaction chamber 4; a gas supply port 6 which supplies argon gas to the reaction chamber 4; a gas discharge port 7 which discharges the argon gas from the reaction chamber 4; a power source 8 which creates an electric field inside the reaction chamber 4; a target 9 which is disposed above the substrate to be processed 2 and discharges a sputtered particle which becomes the metal film 3; and an annular member 10 which surrounds the periphery of the substrate to be processed 2.

As described below, the film forming apparatus 1 forms the metal film 3 on the substrate to be processed 2. First, the substrate to be processed 2 is mounted on the mounting member 5 inside the reaction chamber 4 of the film forming apparatus 1. Next, argon gas is supplied from the gas supply port 6 to the reaction chamber 4. Then, after the temperature inside the reaction chamber 4 reaches 200° C. to 1200° C., an electrical field is created inside the reaction chamber 4 by the power source 8, and argon ions are generated by changing the argon gas into plasma. Next, by making the argon ions collide with the target 9, sputtered particles are discharged from the target 9 and sputtered particles adhere to the substrate to be processed 2. By continuing adhesion of the sputtered particles, it is possible to form the metal film 3 made of the sputtered particles on the substrate to be processed 2.

The film forming apparatus 1 can form the a thin film made of a metal material, such as Ti, Cu, Al, Co, or an alloy including at least one of the metal materials, as the metal film 3 on the substrate to be processed 2. The thermal expansion coefficient of the metal film 3 is, for example, 8.5 ppm/° C. or more and 30 ppm/° C. or less. In addition, the thermal expansion coefficient of the metal film 3 is measured by using a thermo-mechanical analysis (TMA) apparatus which is commercially available. Hereinafter, the thermal expansion coefficient of each member is measured similarly to that of the metal film 3.

(Annular Member)

Next, the annular member 10 to be used in the film forming apparatus 1 will be described in detail.

Since the annular member 10 is disposed on the mounting member 5 and surrounds the periphery of the substrate to be processed 2, the annular member 10 suppresses the adhesion of the sputtered particles to an area where the substrate to be processed 2 is not mounted on the mounting member 5. In addition, the annular member 10 suppresses direct contact of the mounting member 5 to the plasma, and protects a member below the annular member 10 from the plasma. In addition, the annular member 10 is only desired to surround the periphery of the substrate to be processed 2 in plan view, and the annular member 10 may be disposed lower than the substrate to be processed 2, where a position of the annular member 10 in height may be on a mounting member 5 side as compared to a position of the substrate to be processed 2 in height.

The annular member 10 of the embodiment is formed in a circular shape in plan view, and is suitably used when the substrate to be processed 2 is a semiconductor wafer. In addition, the annular member 10 is only desired to have an annular shape, and may have a rectangular annular shape. In this case, the annular member is suitably used when the substrate to be processed 2 is a glass substrate.

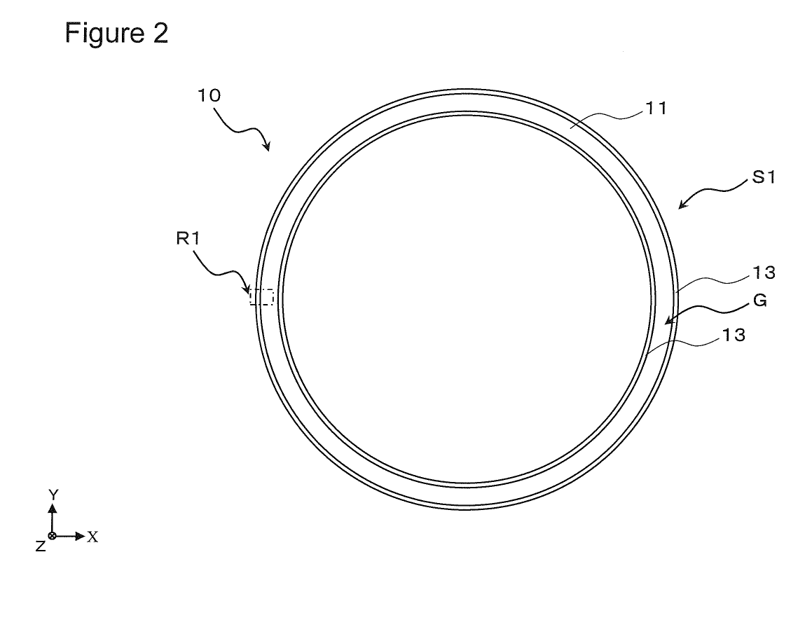

As illustrated in FIG. 2, the annular member 10 includes an annular main body 11 which has at least one main surface S1.

The main body 11 is a main portion of the annular member 10, and is made of an annular ceramic sintered body or quartz glass. As a result, it is possible to use the main body 11 which has good plasma resistance. When the ceramic sintered body is used for the main body 11, it is possible to use an alumina sintered body, an yttria sintered body, a YAG sintered body, or a spinel sintered body, as the ceramic sintered body. Among these, in view of the plasma resistance, strength, and rigidity, it is preferable to use the alumina sintered body, and in view of the plasma resistance, it is preferable to use the yttria sintered body, the YAG sintered body, or the spinel sintered body.

The thickness of the main body 11 is, for example, 3 mm or more and 15 mm or less. In addition, the thermal expansion coefficient of the main body 11 is, for example, 7 ppm/° C. or more and 8 ppm/° C. or less in the case of alumina, and 0.5 ppm/° C. or more and 0.6 ppm/° C. or less in the case of quartz glass.

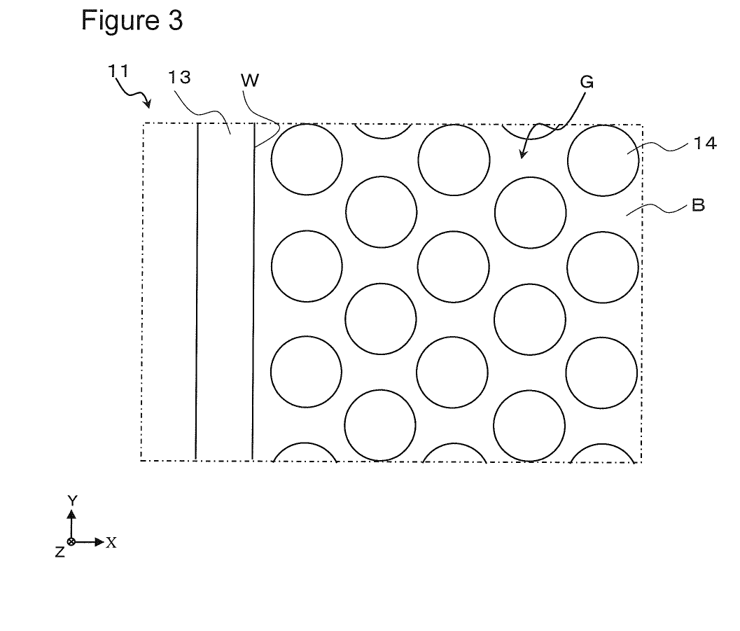

As illustrated in FIGS. 2 to 4, the main body 11 includes a groove portion G disposed on a main surface S1, a bottom portion 12 which constitutes a bottom surface B of the groove portion G, a pair of wall portions 13 which respectively constitute a pair of inner wall surfaces W of the groove portion G, and a plurality of projections 14 which are protruded from the bottom surface B of the groove portion G.

The main surface S1 of the main body 11 is a main surface which is exposed to the inside of the reaction chamber 4 among the pair of main surfaces which are in an annular shape in plan view. The main surface S1 is exposed to the inside of the reaction chamber 4. As a result, when the film forming apparatus 1 is used, the sputtered particles adhere to the main surface S1 and the metal film 3 is deposited. In addition, among the pair of main surfaces of the main body 11, another main surface S2 is not exposed to the inside of the reaction chamber 4.

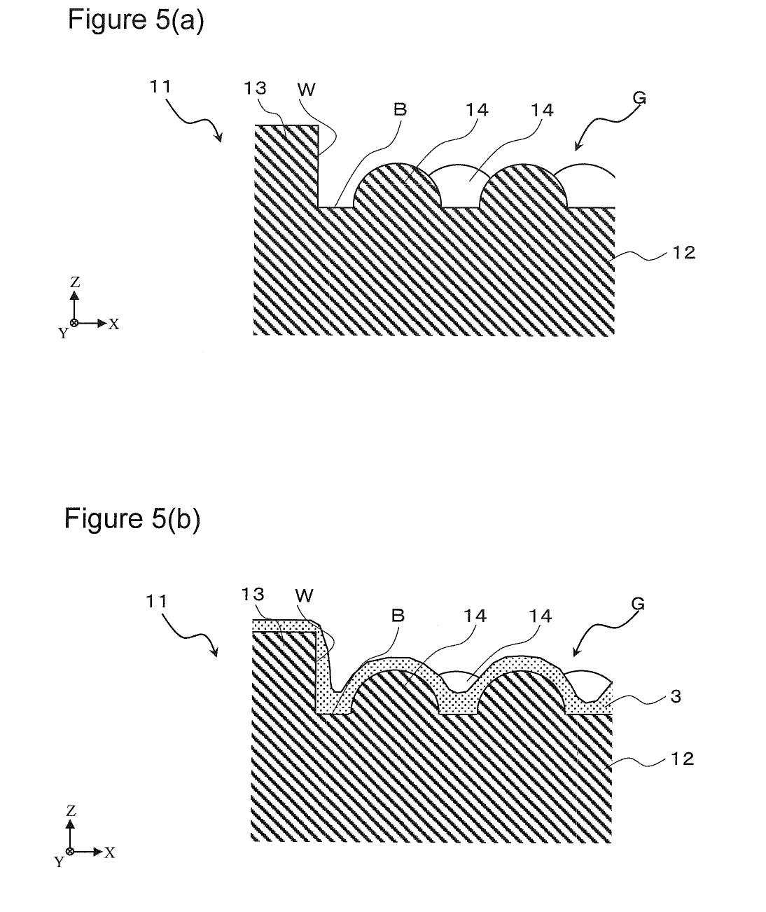

As illustrated in FIGS. 5(a) and (b), the groove portion G is an area which is made as a part of the main surface S1 of the main body 11 is recessed, and an area in which the metal film 3 is deposited. The groove portion G is an area which is surrounded by the bottom surface B and the pair of inner wall surfaces W continuous to the bottom surface B, and is formed in an annular shape along the annular main body 11. As illustrated in FIG. 2, it is preferable that the groove portion G be formed in the entire circumferential direction of the annular main body 11, but the groove portion G may be formed in a part of the annular main body 11 in the circumferential direction. A depth (in Z direction) of the groove portion G is, for example, 1 mm or more and 10 mm or less. In addition, a width of the groove portion (perpendicular to the circumferential direction of the groove portion G) is, for example, 10 mm or more and 40 mm or less.

The bottom portion 12 is a part of the main body 11, has the bottom surface B as one surface, and is positioned directly under the bottom surface B. The bottom portion 12 is formed in an annular shape along the groove portion G.

The pair of wall portions 13 have the inner wall surfaces W as a surface, and are respectively disposed on an inner side (inner diameter side of the annular member 10) and on an outer side (outer diameter side of the annular member 10) of the annular-shaped groove portion G. Each of the pair of wall portions 13 is formed in an annular shape along the groove portion G.

The projection 14 is a part of the main body 11, which is protruded from the bottom surface B of the groove portion G, is integrally formed with the main body 11, and is made of the same material as the main body 11. A height of the projection 14 is, for example, 0.5 mm or more and 10 mm or less. In addition, a width of the projection 14 is, for example, 1 mm or more and 20 mm or less.

As described above, the formation of the metal film 3 on the substrate to be processed 2 is performed under a condition of high temperature from 200° C. to 1200° C. At that time, the metal film 3 is deposited inside the groove portion G of the annular member 10. When the temperature inside the reaction chamber 4 decreases after the film is formed, the metal film 3 deposited inside the groove portion G contracts more than the main body 11 because of the difference between the thermal expansion coefficient of the main body 11 of the annular member 10 and the thermal expansion coefficient of the metal film 3. Accordingly, thermal stress is easily applied to the bottom portion 12 of the main body 11.

Meanwhile, in the embodiment, the main body 11 has the plurality of projections 14 protruded from the bottom surface B of the groove portion G. Accordingly, it is possible to divide the metal film 3 deposited in the groove portion G into small areas in a plane direction by the plurality of projections 14. Therefore, when the temperature inside the reaction chamber 4 decreases after finishing the formation of the metal film 3, the metal film 3 contracts in the plane direction in each area divided by the projections 14. Accordingly, compared to a case where the metal film 3 contracts greatly in the plane direction across the entire bottom surface B, the thermal stress applied to the bottom portion 12 of the main body 11 can be dispersed. Therefore, it is possible to reduce cracks in the bottom portion 12 of the main body 11, and to obtain the annular member 10 which has good reliability.

In addition, by using the plurality of projections 14, a bonding area between the main body 11 and the metal film 3 in the groove portion G increases, and an anchor effect is created. Accordingly, it is possible to reduce peeling of the metal film 3 from the groove portion G. As a result, it is possible to reduce contamination of the substrate to be processed 2 due to the peeled metal film 3. In addition, in this manner, by reducing the peeling of the metal film 3 from the groove portion G, it is possible to make an easy maintenance of the annular member 10.

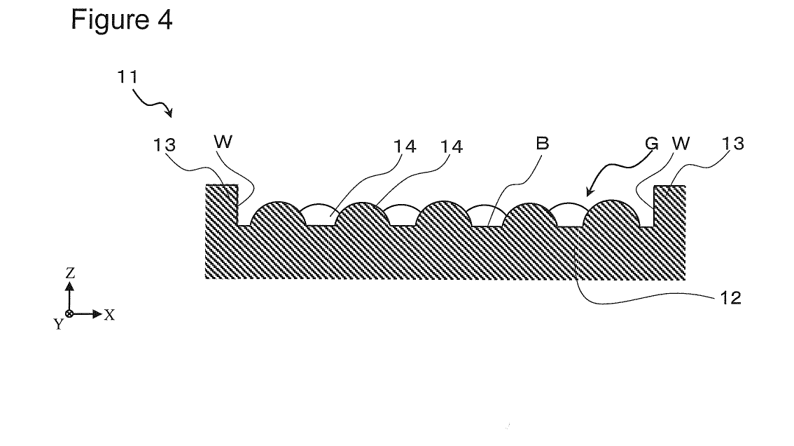

In addition, as illustrated in FIGS. 4, 6(a), and 7(a), the surface of each of the plurality of projections 14 is spherical. As a result, a corner is unlikely to be created on the surface of the projection 14. Accordingly, when the metal film 3 adheres to the surface of the projection 14 and thermal stress is created between the projection 14 and the metal film 3, it is possible to disperse the thermal stress on the surface of the projection 14, and to reduce the peeling of the metal film 3 from the projection 14.

In addition, as illustrated in FIGS. 4, 6(a), and 7(a), the width of each of the plurality of projections 14 becomes smaller toward a tip end portion from the bottom surface B, and the plurality of projections 14 have a tapered shape, particularly, a hemispherical shape. As a result, the sputtered particles 10 are likely to enter the groove portion G, and likely to adhere to the bottom surface B. Therefore, an amount of the metal film 3 deposited inside the groove portion G can be increased.

In addition, the height of the projection 14 is lower than the depth of the groove portion G. In other words, a head of the projection 14 is positioned on the bottom surface B side than an opening of the groove portion G. As a result, by making the height position of the metal film 3 deposited on the surface of the projection 14 closer to the height position of the bottom surface B, it is possible to reduce the contamination of the substrate to be processed 2 by the metal film 3.

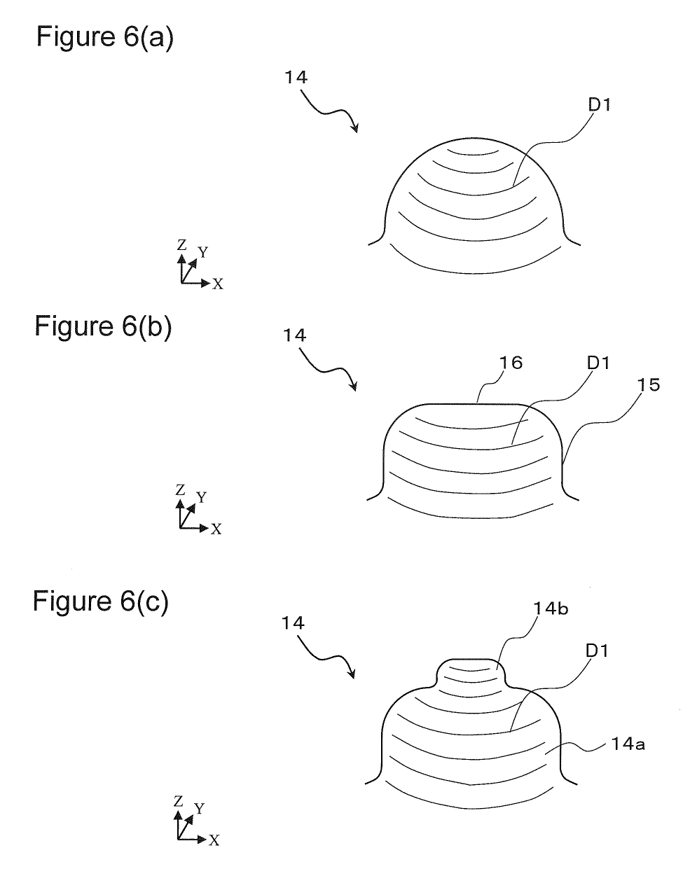

In addition, as illustrated in FIG. 6(a), the surface of each of the plurality of projections 14 has a plurality of first recessed portions D1 which are in an elongated shape along the circumferential direction of the projection 14. As a result, by the anchor effect, it is possible to enhance bonding strength between the projection 14 and the metal film 3, reduce the peeling of the metal film 3 from the projection 14, and to reduce the contamination of the substrate to be processed 2 by the metal film 3.

Furthermore, in the embodiment, the surface of the projection 14 is a fired surface. The fired surface is a surface which has not been subjected to surface treatment after obtaining a ceramic sintered body by firing as described later, and is a smooth surface compared to a case where the surface treatment, such as blasting, is performed. Accordingly, with the fired surface, the cleaning to reduce the bonding strength between the projection 14 and the metal film 3 and to remove the metal film 3 from the projection 14 can easily be performed on the projection 14. Therefore, since the projection 14 has both the fired surface and the first recessed portion D1, it is possible to adjust the bonding strength between the projection 14 and the metal film 3, and to easily perform cleaning and remove the metal film 3 from the projection 14 while reducing the contamination of the substrate to be processed 2 by the metal film 3.

In addition, since the surface of the projection 14 is the fired surface, as compared to a case where the surface treatment, such as blasting, is performed, it is possible to suppress generation of microcracks on the surface of the projection 14, and to suppress detachment of particles from the projection 14. Therefore, since it is possible to suppress flying of a part of the metal film 3 with the particles, it is possible to reduce the contamination of the substrate to be processed 2 by the metal film 3.

On the surface of the projection 14, the plurality of the first recessed portions D1 are formed in a concentric circular shape. In addition, a depth of the first recessed portion D1 is, for example, 10 μm or more and 500 μm or less. In addition, a width of the first recessed portion D1 is, for example, 10 μm or more and 500 μm or less.

In addition, as illustrated in FIGS. 4, 6(a), and 7(a), an angle of a corner portion which is made of the side surface of each of the plurality of projections 14 and the bottom surface B continuous to the side surface, is greater than 90° and less than 180°. As a result, as the corner portion becomes an obtuse angle, and it is possible to deposit the metal film 3 suitably even on the corner portion. It is desirable that the angle of the corner portion be greater than 90° and equal to or less than 120°.

(Method of Manufacturing Annular Member)

Next, a method of manufacturing the annular member 10 according to the embodiment will be described by using an example in which the ceramic sintered body is used for the main body 11.

First, after adding pure water and an organic binder to ceramic powder (primary particle), slurry is prepared by wet blending in a ball mill. Next, the slurry is granulated by spray-drying. Then, the granulated ceramic particles (secondary particles) are molded by using various molding methods, and a molded body is prepared. Next, the molded body is subjected to cutting, and the molded body has a desired shape. Next, by firing the molded body, for example, at 1400° C. or higher and 1800° C. or lower, the ceramic sintered body is prepared. Then, the ceramic sintered body is subjected to grinding, and the main body 11 made of the ceramic sintered body in the desired shape is manufactured.

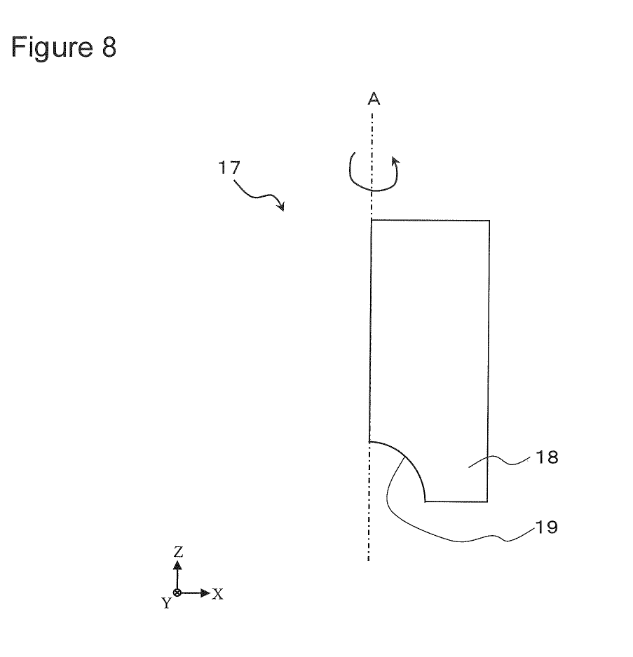

Here, in the embodiment, the cutting of the molded body is performed as described below. First, the main surface of the molded body is cut by turning, and a part of the groove portion is formed. The part of the groove portion is a part of the groove portion G in a depth direction after manufacturing the annular member 10, and the depth of the part of the groove portion is shallower than that of the groove portion G. Next, by milling using a cutting tool, such as a carbide or compax diamond tool, the bottom surface of the part of the groove portion is cut, and the projection 14 is formed. During the milling, by using a cutting tool 17 which has a desired tip end shape, it is possible to obtain the projection 14 in the desired shape. Specifically, as illustrated in FIG. 8, by using the cutting tool 17 which has a slit 19 in a curved shape at a corner of a tip end portion 18, a rotation axis A is disposed on the slit 19 side of the cutting tool 17, and the milling is performed. While rotating the slit 19, a part of the bottom surface of the groove portion is cut. As a result, it is possible to form the projection 14 in a spherical shape corresponding to the shape of the slit 19.

In addition, in the embodiment, after forming the groove portion G and the projection 14 in the molded body by cutting, and after firing the molded body, the surface treatment, such as grinding, is not performed on the groove portion G and the projection 14. As a result, it is possible to make the surface of the groove portion G and the projection 14 into the fired surface. In addition, when milling is performed by using a cutting tool with a projection portion (not illustrated) formed on an inner surface of the slit 19 as the cutting tool 17, a cutting trace in an elongated shape is formed on the surface of the projection 14 along the circumferential direction of the projection 14. As described above, when the surface of the projection 14 is a fired surface, the cutting trace remains on the surface of the projection 14 and becomes the first recessed portion D1.

Next, a method of manufacturing the annular member 10 according to the embodiment will be described by using an example in which the quartz glass is used for the main body 11.

First, a raw material is melted and poured into a mold, and the quartz glass is prepared. Next, by performing cutting on the quartz glass, the main body 11 made of the quartz glass in a desired shape can be manufactured.

Here, in the case of the quartz glass, such a cutting tool as a carbide or compax diamond tool is used, and the groove portion G is formed on the main surface S1 of the quartz glass and the projection 14 is formed on the bottom surface B of the groove portion G. During the milling, by using a cutting tool which has a desired tip end shape, it is possible to obtain the projection 14 in the desired shape. In addition, with the cutting trace remaining in the elongated shape along the circumferential direction of the projection 14 on the surface of the projection 14, it is possible to form the first recessed portion D1.

### Second Embodiment

Next, an annular member according to a second embodiment of the invention will be described in detail with reference to the drawings. Description of a configuration which is similar to that of the above-described first embodiment will be omitted.

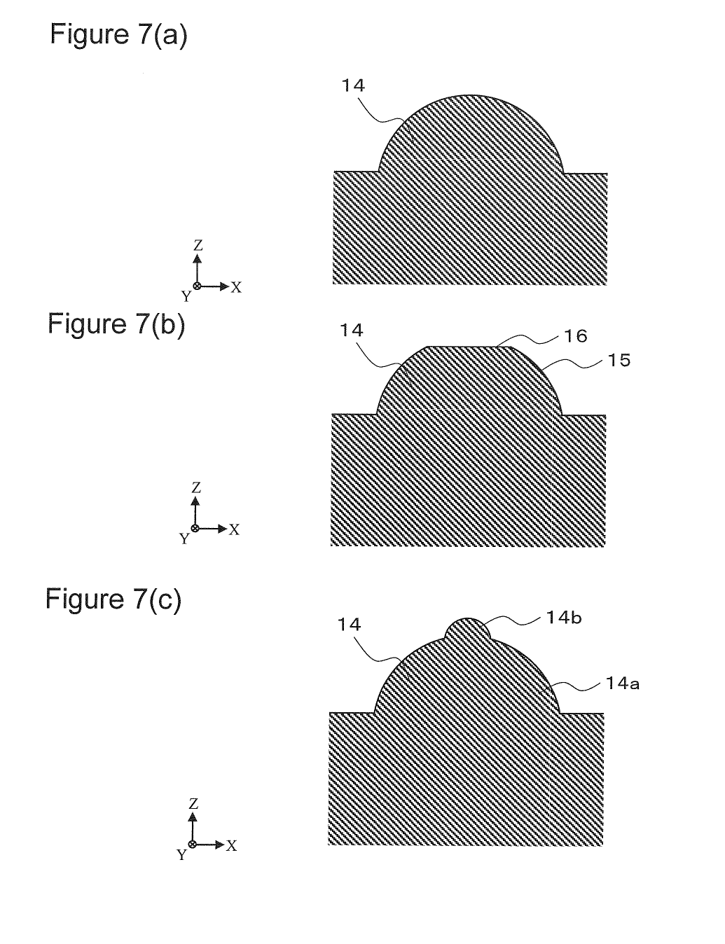

As illustrated in FIGS. 6(b) and 7(b), the annular member 10 of the second embodiment is different from the annular member 10 of the first embodiment in the shape of the projection 14. A surface of a projection 14 of the embodiment includes a spherical side surface 15 and a planar head surface 16. As a result, the thermal stress between the side surface 15 and the metal film 3 can be dispersed by the spherical side surface 15, and a height position of the head surface 16 in each of the plurality of projections 14 can be made equal. Therefore, it is possible to make the height position of the metal film 3 more uniform.

The projection 14 of the embodiment can be formed by using a cutting tool which has a desired tip end shape during the milling in the method of manufacturing the annular member 10 of the first embodiment.

In addition, the projection 14 of the embodiment may be formed by cutting the head of the projection 14 in turning after forming the projection 14 made of the spherical surface by performing the milling on the molded body similarly to the first embodiment. In this case, it is possible to easily make the height position of the head surface 16 of the projections 14 equal. In addition, after performing turning on the molded body similarly to the first embodiment, the projection 14 is formed by milling while the bottom surface formed by the turning remains, and the bottom surface formed by the turning may be the head surface 16 of the projection 14. In this case also, it is possible to easily make the height position of the head surface 16 of the projections 14 equal.

### Third Embodiment

Next, an annular member according to a third embodiment of the invention will be described in detail with reference to the drawings. Description of a configuration which is similar to that of the above-described first and second embodiments will be omitted.

As illustrated in FIGS. 6(c) and 7(c), the annular member 10 of the third embodiment is different from the annular member 10 of the first and second embodiments in the shape of the projection 14. The surface of the projection 14 of the embodiment includes a first protruded portion 14a protruded from the bottom surface B and a second protruded portion 14b which is protruded from the first protruded portion 14a and has a width narrower than the first protruded portion 14a. As a result, it is possible to increase the bonding area between the projection 14 and the metal film 3, and to improve the bonding strength between the projection 14 and the metal film 3.

It is desirable that each of the surfaces of the first protruded portion 14a and the second protruded portion 14b be in a spherical shape. As a result, it is possible to disperse the thermal stress added between the first and second protruded portions 14a and 14b, and the metal film 3.

A width of the first protruded portion 14a is, for example, 1 mm or more and 20 mm or less. In addition, a width of the second protruded portion 14b is, for example, 0.3 mm or more and 18 mm or less. A height of the first protruded portion 14a is, for example, 0.4 mm or higher and 9.9 mm or lower. In addition, a height of the second protruded portion 14b is, for example, 0.1 mm or higher and 5 mm or lower.

The projection 14 of the embodiment can be formed by using a cutting tool which has a desired tip end shape during the milling in the method of manufacturing the annular member 10 of the first embodiment.

In addition, the projection 14 of the embodiment may be formed by appropriately adjusting a position of the rotation axis A of the cutting tool 17 during the milling in the method of manufacturing the annular member 10 of the first embodiment.

### Fourth Embodiment

Next, an annular member according to a fourth embodiment of the invention will be described in detail with reference to the drawings. Description of a configuration which is similar to that of the above-described first to third embodiments will be omitted.

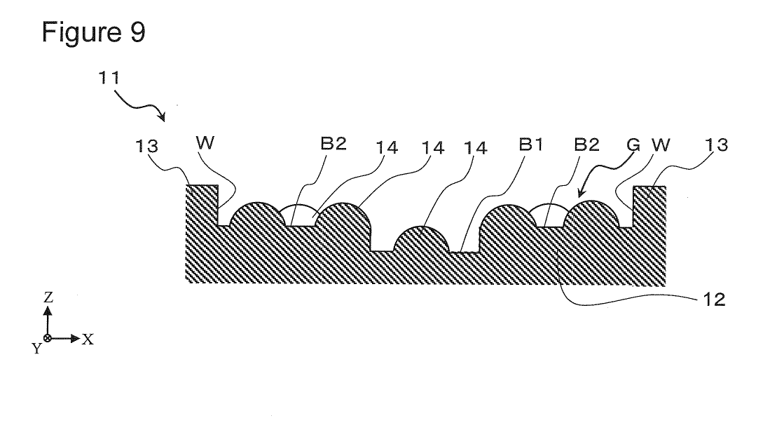

As illustrated in FIG. 9, the annular member 10 of the fourth embodiment is different from the annular member 10 of the first to third embodiments in the shape of the bottom surface B of the groove portion G. The bottom surface B of the groove portion G of this embodiment has a stepped shape and includes a first surface area B1 and a second surface area B2 of which height positions are different from each other. In this manner, when the bottom surface B has a stepped shape, it is possible to adjust the height position of the metal film 3 on the head surface. For example, compared to other areas, at an area in which the height position on the bottom surface B is low (close to another main surface S2), the metal film 3 can be deposited while the height position of the metal film 3 on the head surface being lowered. Therefore, by lowering the height position of the area where a deposition amount of the metal film 3 is likely to increase, it is possible to reduce the contamination of the substrate to be processed 2 by the metal film 3, and to deposit a larger amount of metal film 3 in the groove portion G. In addition, the bottom surface B has two steps in the embodiment, but the bottom surface B may have three or more steps.

In addition, the height position of the first surface area B1 is lower than the height position of the second surface area B2. In other words, a depth of the first surface area B1 is deeper than the depth of the second surface area B2. Furthermore, as illustrated in FIG. 9, the first surface area B1 is positioned at the center in a width direction of the annular member 10, and the second surface areas B2 are disposed on both sides thereof. In this manner, the annular member 10 has the first surface area B1 in the center part in the width direction. Therefore, when the metal film 3 is likely to be deposited in the center part, it is possible to reduce the contamination of the substrate to be processed 2 by the metal film 3, and to deposit a larger amount of metal film 3 in the groove portion G. In addition, it is desirable that the first surface area B1 and the second surface area B2 be formed along the circumferential direction of the annular member 10. Furthermore, it is desirable that the first surface area B1 and the second surface area B2 be formed in the entire circumferential direction of the annular member 10.

In addition, the first surface area B1 and the second surface area B2 are in a planar shape. In addition, in each of the first surface area B1 and the second surface area B2, at least one projection 14 is formed. Furthermore, it is desirable that the first surface area B1 and the second surface area B2 be formed along the circumferential direction of the annular member 10, and a plurality of projections 14 be formed along the circumferential direction in each of the first surface area B1 and the second surface area B2.

The groove portion G of the embodiment can be formed by performing milling on each of the first surface area B1 and the second surface area B2 after performing processing to make the height position of the first surface area B1 lower than the height position of the second surface area B2 during the turning in the method of manufacturing the annular member 10 of the first embodiment.

### Fifth Embodiment

Next, an annular member according to a fifth embodiment of the invention will be described in detail with reference to the drawings. Description of a configuration which is similar to that of the above-described first to fourth embodiments will be omitted.

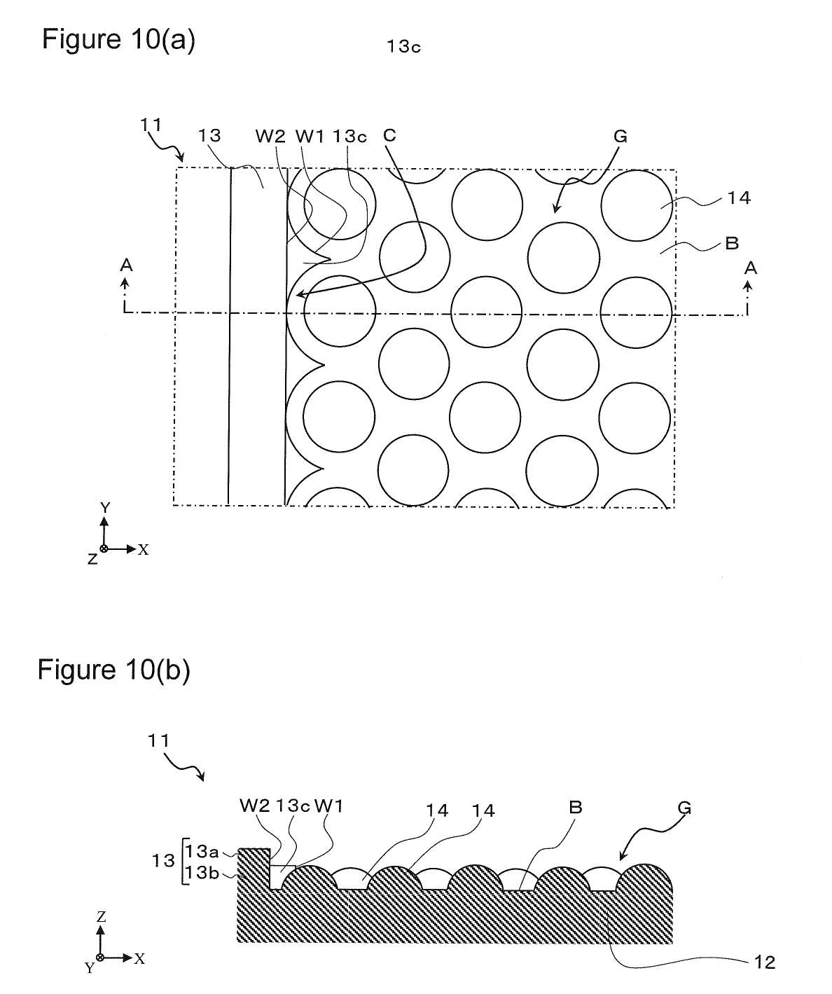

As illustrated in FIG. 10, the annular member 10 of the fifth embodiment is different from the annular member 10 of the first to fourth embodiments in the shape of the inner wall surface W of the groove portion G. In this embodiment, the main body 11 has a plurality of concave portions C in an elongated shape along a depth direction (Z direction) of the groove portion G on the inner wall surface W of the groove portion G. As a result, it is possible to increase the bonding area between the inner wall surface W and the metal film 3, and to enhance the bonding strength between the inner wall surface W and the metal film 3 by the anchor effect. Therefore, it is possible to reduce the peeling of the metal film 3 from the inner wall surface W.

The concave portion C is formed in a curved shape in plan view, for example, and furthermore, is formed in a circular shape in plan view. As a result, it is possible to disperse the thermal stress between the inner wall surface W and the metal film 3 in the concave portion C. In addition, in plan view, the radius of curvature of the concave portion C is, for example, 0.8 mm or more and 15 mm or less.

In the embodiment, the inner wall surface W includes a first surface area W1 which is positioned at the bottom surface B side and has the concave portion C, and a second surface area W2 which is positioned closer to the opening side of the groove portion G than the first surface area W1 and has a planar shape without the concave portion C. In addition, the wall portion 13 includes a first portion 13a which is positioned at the bottom surface B side and constitutes the first surface area W1, and a second portion 13b which is positioned at the opening side of the groove portion G and constitutes the second surface area W2. The first portion 13a of the wall portion 13 includes a protruded area 13c that is disposed between the concave portions C which are adjacent to each other and is protruded toward the groove portion G side than the second surface area W2. As a result, it is possible to enhance the strength of the wall portion 13 with respect to tensile stress toward the groove portion G. Therefore, it is possible to reduce occurrence of cracks between the wall portion 13 and the bottom portion 12 when the temperature inside the reaction chamber 4 decreases after finishing the formation of the metal film 3 and the tensile stress toward the groove portion G is added to the wall portion 13 by contraction of the metal film 13.

In the groove portion G of the embodiment, the concave portion C can be formed on the inner wall surface W of the groove portion G by performing cutting along the circumferential direction of the projection 14 while a part of the inner wall surface W remaining, during the milling in the method of manufacturing the annular member 10 of the first embodiment.

In addition, after preparing the molded body, by performing the milling without performing the turning, the concave portion C may be formed on the inner wall surface W in the depth direction of the groove portion G. In this case, it is possible to enhance the bonding strength between the inner wall surface W and the metal film 3.

### Sixth Embodiment

Next, an annular member according to a sixth embodiment of the invention will be described in detail with reference to the drawings. Description of a configuration which is similar to that of the above-described first to fifth embodiments will be omitted.

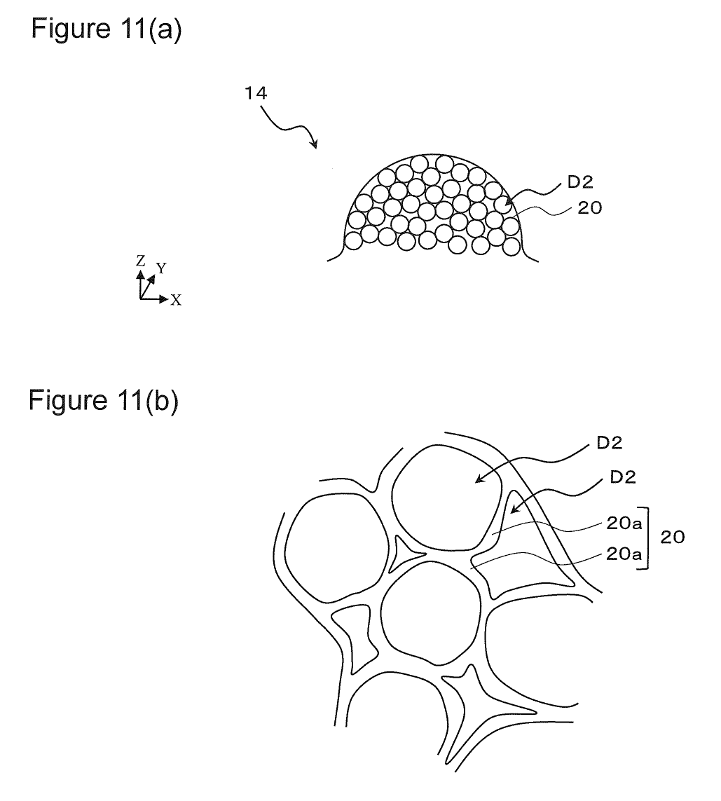

As illustrated in FIGS. 11(a) and 11(b), the annular member 10 of the sixth embodiment is different from the annular member 10 of the first to fifth embodiments in the shape of the surface of the projection 14. In this embodiment, each of the surfaces of the plurality of projections 14 includes a convex portion 20 in a mesh shape along the surface, and a plurality of second recessed portions D2 surrounded by the convex portion 20. As a result, unevenness in a complicated shape is formed on each of the surfaces of the plurality of projections 14. Therefore, it is possible to create the anchor effect with respect to stress in various directions, and to enhance the bonding strength between the projections 14 and the metal film 3.

In the convex portion 20 in a mesh shape, a plurality of parts 20a which are in an elongated shape along the surface of the projection 14 are connected to each other, and look similar to a mesh shape formed on the surface of the muskmelon, for example. A height of the convex portion 20 is, for example, 5 μm or more and 30 μm or less. In addition, a width of the convex portion 20 is, for example, 3 μm or more and 30 μm or less.

The plurality of second recessed portions D2 surrounded by the convex portion 20 are adjacent to each other on the surface of the projection 14, look similar to the appearance of dimples on a golf ball, for example. The second recessed portion D2 has, for example, a circular shape or a polygonal shape. When the second recessed portion D2 has a circular shape, it is possible to easily perform cleaning to remove the metal film 3 from the projection 14. In addition, when the second recessed portion D2 has a polygonal shape, it is possible to form the second recessed portions D more densely, and to enhance the anchor effect by the second recessed portions D. A depth of the second recessed portion D is, for example, 5 μm or more and 30 μm or less. A width of the second recessed portion D is, for example, 10 μm or more and 200 or less.

In addition, it is desirable that an inner surface of the second recessed portion D be in a concave curved surface shape. As a result, since the metal film 3 is likely to enter the second recessed portion D, it is possible to reduce a gap between the second recessed portion D and the metal film 3. Accordingly, it is possible to enhance the anchor effect by the second recessed portions D.

When the main body 11 is made of a ceramic sintered body, it is desirable that the second recessed portion D be larger than the primary particle of the ceramic sintered body. Furthermore, it is desirable that the second recessed portion D be larger than a grain size of the ceramic sintered body which constitutes the main body 11.

In the embodiment, each surface of the plurality of projections 14 is the fired surface. As a result, similarly to the first embodiment, compared to a case where the surface treatment, such as blasting, is performed, it is possible to easily perform cleaning to remove the metal film 3 from the projection 14, to suppress the occurrence of microcracks on the surface of the projections 14, and to suppress detachment of the particles from the projection 14.

The convex portion 20 and the second recessed portion D2 of the embodiment can be formed as described below, for example. First, in a case where the ceramic sintered body is used for the main body 11 in the method of manufacturing the annular member 10 of the first embodiment, when the milling is performed, by rotating the cutting tool 17 plural times without changing the position thereof, the slit 19 is rotated plural times with respect to the surface of the projection 14 and a zero-cutting is performed. Next, by firing the molded body, it is possible to form the convex portion 20 and the second recessed portions D2 of the embodiment. It is assumed that this is caused by pushing a cutting chip, such as the secondary particle created by the cutting process, to the surface of the projection 14 by zero-cutting. As described above, when the surface of the projection 14 is a fired surface, the convex portion 20 and the second recessed portions D remain on the surface of the projection 14.

In addition, in order to form the convex portion 20 in a mesh shape and the second recessed portion D, it is desirable that a feed rate of the cutting tool 18 be F0.1 mm/min to F100 mm/min, and a spindle rotation speed of the cutting tool 18 be S1400 rpm to S1600 rpm.

### Seventh Embodiment

Next, an annular member according to a seventh embodiment of the invention will be described in detail with reference to the drawings. Description of a configuration which is similar to that of the above-described first to sixth embodiments will be omitted.

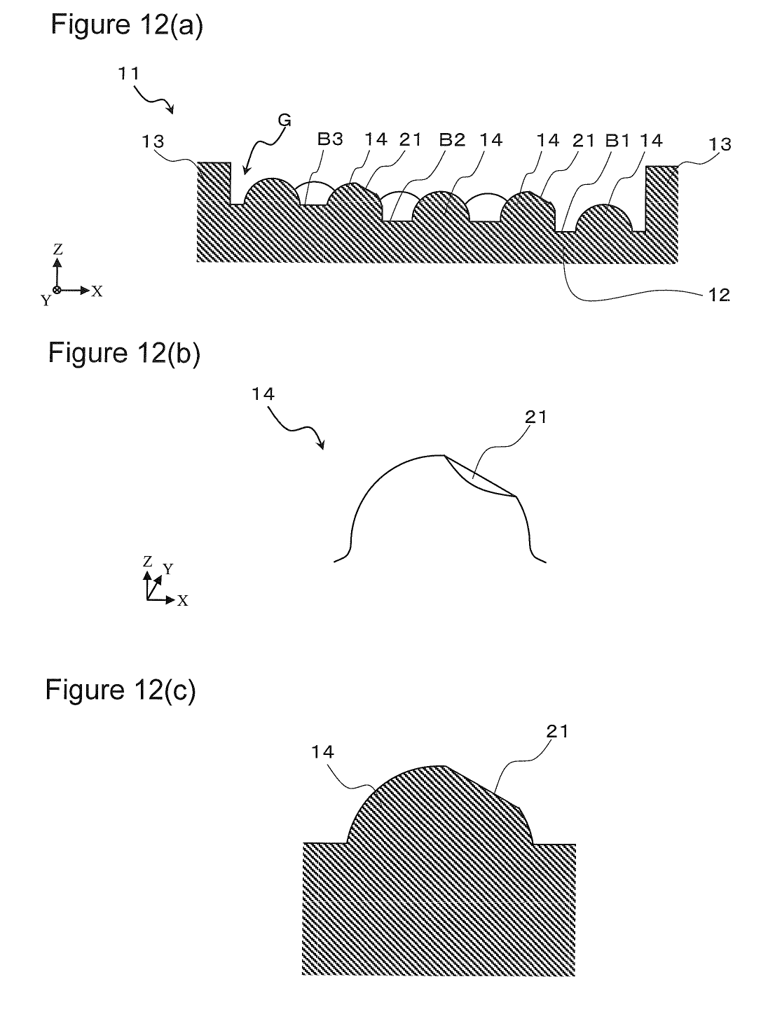

As illustrated in FIGS. 12(a) to 12(c), the annular member 10 of the seventh embodiment is different from the annular member 10 of the first to sixth embodiments in the shape of the projection 14. In this embodiment, the projection 14 has a flat surface 21 which is inclined with respect to the bottom surface B of the groove portion G. As a result, after finishing the formation of the film in the film forming apparatus 1, when the argon gas inside the reaction chamber 4 is discharged to the outside, the argon gas flows along the inclined flat surface 21. Accordingly, it is possible to control the flow of the argon gas by making the shape of the flat surface 21 into a desired shape. Therefore, by controlling the flow of the argon gas, it is possible to enhance discharging efficiency of the argon gas, and to enhance processing efficiency of the film forming apparatus 1.

An inclination angle of the flat surface 21 with respect to the bottom surface B is, for example, 1° or more and 89° or less.

In addition, as illustrated in FIG. 12(a), in the annular member 10 of this embodiment, the bottom surface B of the groove portion G has a stepped shape similarly to the annular member 10 of the fourth embodiment, but the shape of the bottom portion B is different from that of the annular member 10 of the fourth embodiment. The bottom surface B of the groove portion G of this embodiment includes: a first surface area B1; a second surface area B2 which is disposed closer to an outer diameter side of the annular member 10 than the first surface area B1 and in which a height position is higher than that of the first surface area B1; and a third surface area B3 which is disposed closer to the outer diameter side of the annular member 10 than the second surface area B2 and in which a height position is higher than that of the second surface area B2. In other words, the height position of the bottom surface B of the groove portion G becomes lower toward the inner diameter side (inner side of the groove portion G) from the outer diameter side (outer side of the groove portion G) of the annular member 10. Therefore, when the metal film 3 is likely to be deposited on the inner diameter side of the annular member 10, it is possible to reduce the contamination of the substrate to be processed 2 by the metal film 3, and to deposit a larger amount of metal film 3 in the groove portion G.

In addition, in each of the first surface area B1, the second surface area B2, and the third surface area B3, at least one projection 14 is disposed. The surface of the projection 14 disposed in the second surface area B2 has the flat surface 21 inclined toward the first surface area B1. The flat surface 21 is inclined such that the height position of an end portion on the first surface area B1 side becomes lower than the height position of the other end portion on a side opposite to the first surface area B1. As a result, when the argon gas inside the reaction chamber 4 is discharged to the outside, by using the flat surface 21, it is possible to move the argon gas to the outer diameter side of the annular member 10 from the inner diameter side of the annular member 10 with high efficiency, and to enhance the discharging efficiency of the argon gas.

In addition, similarly to the surface of the projection 14 disposed in the second surface area B2, the surface of the projection 14 disposed in the third surface area B3 has the flat surface 21 inclined toward the second surface area B2. In this case, as described above, it is possible to move the argon gas to the outer diameter side of the annular member 10 from the inner diameter side of the annular member 10 with high efficiency.

As described below, the groove portion G of this embodiment can be formed. First, a part of the groove portion is formed by performing processing to incline the bottom surface toward the inner diameter side from the outer diameter side of the annular member 10 during the turning in the method of manufacturing the annular member 10 of the first embodiment. The part of the groove portion has a depth on the outer diameter side of the annular member 10 smaller than a depth on the inner diameter side thereof. Next, during the milling, by cutting the inclined bottom surface of the part of the groove portion, the first surface area B1, the second surface area B2, and the third surface area B3, which have different height positions from each other as described above, are formed, and the plurality of projections 14 disposed in each area are formed. During the milling, when the inclined bottom surface of the part of the groove portion remains on the surface of the projection 14, it is possible to make the inclined bottom portion into an inclined flat surface 21.

The invention is not limited to the above-described embodiments, and various modifications, improvements, or combinations are possible without departing from the scope of the invention.

For example, in the above-described embodiments, a configuration in which a sputtering apparatus is used as the film forming apparatus provided with the annular member is described as an example. However, as long as the film forming apparatus forms a metal film, the apparatus may be used, and a PVD apparatus or a metal CVD apparatus can be used as the film forming apparatus in addition to the sputtering apparatus, for example.

In addition, in the above-described embodiments, a configuration in which the argon gas is used as gas which generates the plasma inside the reaction chamber of the film forming apparatus is described as an example. However, another gas may be used as gas which generates plasma.

In addition, in the above-described embodiment, a configuration in which the surface of the projection is a fired surface is described as an example. However, the surface of the projection may be subjected to the surface treatment, such as blasting.

### REFERENCE SIGNS LIST

1 Film forming apparatus
2 Substrate to be processed
3 Metal film
4 Reaction chamber
5 Mounting member
6 Gas supply port
7 Gas discharge port
8 Power source
9 Target
10 Annular member
11 Main body
12 Bottom portion
13 Wall portion
14 Projection
15 Side surface
16 Head surface
17 Cutting tool
18 Tip end portion
19 Slit
20 Convex portion
21 Flat surface
S1 One main surface
S2 Another main surface
G Groove portion
B Bottom surface
W Inner wall surface
D1 First recessed portion
D2 Second recessed portion

1. An annular member which surrounds the periphery of a substrate to be processed, comprising:
an annular main body which is made of a ceramic sintered body or quartz glass, and includes at least one main surface,
wherein the main body includes a groove portion disposed on one main surface and a plurality of projections protruded from a bottom surface of the groove portion.

2. The annular member according to claim 1,
wherein a surface of each of the plurality of projections is spherical.

3. The annular member according to claim 1,
wherein a surface of each of the plurality of projections includes a spherical side surface and a planar head surface.

4. The annular member according to claim 1,
wherein a surface of each of the plurality of projections has a plurality of recessed portions in an elongated shape along a circumferential direction of the projection.

5. The annular member according to claim 1,
wherein a surface of each of the plurality of projections has a convex portion in a mesh shape along the surface.

6. The annular member according to claim 5,
wherein the surface of each of the plurality of projections has a plurality of second recessed portions surrounded by the convex portion.

7. The annular member according to claim 6,
wherein an inner surface of each of the second recessed portions is in a concave curved surface shape.

8. The annular member according to claim 1,
wherein the bottom surface of the groove portion is in a stepped shape and includes a first surface area and a second surface area of which height positions are different from each other.

9. The annular member according to claim 8,
wherein a distance between the first surface area and another main surface of the main body is smaller than a distance between the second surface area and the other main surface of the main body, and
wherein, among the plurality of projections, at least one of the projections is disposed in the second surface area, and the surface of the projection disposed in the second surface area has a flat surface inclined toward the first surface area.

10. The annular member according to claim 1,
wherein the main body includes a plurality of concave portions in an elongated shape along a depth direction of the groove portion on an inner wall surface of the groove portion.

11. The annular member according to claim 1,
wherein an angle of a corner portion between a side surface of each of the plurality of projections and the bottom surface continuous to the side surface is larger than 90° and smaller than 180°.

12. The annular member according to claim 1,
wherein each of the plurality of projections includes a first protruded portion protruded from the bottom surface and a second protruded portion protruded from the first protruded portion and having a width narrower than the first protruded portion.

13. A film forming apparatus, comprising:
the annular member according to claim 1; and
a reaction chamber in which the annular member is disposed, and which performs formation of a metal film on the substrate to be processed,
wherein the groove portion of the annular member is exposed to the inside of the reaction chamber.
